(19) United States
(12) Patent Application Publication
(10) Pub. No.: US 2024/0138226 A1
(43) Pub. Date: Apr. 25, 2024

(54) DISPLAY DEVICE

(71) Applicant: Samsung Display Co., LTD., Yongin-si (KR)

(72) Inventors: SUN-KYU JOO, Yongin-si (KR); DAEHYEON KIM, Yongin-si (KR); Hong Il Kim, Yongin-si (KR); SANGJI PARK, Yongin-si (KR); KEUNCHAN OH, Yongin-si (KR); DOKYUNG YOUN, Yongin-si (KR); SONGEE LEE, Yongin-si (KR); CHANG-MIN LEE, Yongin-si (KR); HYUNSHIK LEE, Yongin-si (KR); WOO-MAN JI, Yongin-si (KR); TAE HYUNG HWANG, Yongin-si (KR)

(21) Appl. No.: 18/450,862

(22) Filed: Aug. 15, 2023

(30) Foreign Application Priority Data
Oct. 24, 2022 (KR) 10-2022-0137848

(51) Int. Cl. H10K 59/38; H10K 59/12

(52) U.S. Cl. CPC H10K 59/38; H10K 59/12; H10K 2102/331

(57) ABSTRACT

A display device includes: a blue color filter layer in a blue transmission region of an upper substrate, and including first scattering particles; a green color filter layer in a green transmission region of the upper substrate, and including second scattering particles; a red color filter layer in a red transmission region of the upper substrate; a partition wall on the upper substrate and defining a blue transmission opening, a green transmission opening, and a red transmission opening, which overlap the blue transmission region, the green transmission region, and the red transmission region, respectively; a color conversion layer including red color conversion particles and third scattering particles, and accommodated in the red transmission opening; a light emitting element layer on a lower substrate facing the upper substrate; and a filling material between the upper substrate and the lower substrate.

### CROSS-REFERENCE TO RELATED APPLICATION

The present application claims priority to and the benefit of Korean Patent Application No. 10-2022-0137848 filed on Oct. 25, 2022, in the Korean Intellectual Property Office (KIPO), the entire disclosure of which is incorporated herein by reference.

### BACKGROUND

### 1. Field

Aspects of some embodiments of the present disclosure relate to a display device.

### 2. Description of the Related Art

A display device refers to a device configured to display images, and may include a plurality of pixels configured to emit light. In order to improve display quality of the display device, the display device may include various components for improving light output efficiency of the light emitted from the pixels.

The above information disclosed in this Background section is only for enhancement of understanding of the background and therefore the information discussed in this Background section does not necessarily constitute prior art.

### SUMMARY

Aspects of some embodiments of the present disclosure include a display device with relatively improved display quality.

However, characteristics of some embodiments of the present disclosure are not limited to the above-described characteristics, and may be variously expanded and changed without departing from the spirit and scope of embodiments according to the present disclosure.

According to some embodiments of the present disclosure, a display device includes: a blue color filter layer in a blue transmission region of an upper substrate, and including first scattering particles; a green color filter layer in a green transmission region of the upper substrate, and including second scattering particles; a red color filter layer in a red transmission region of the upper substrate; a partition wall on the upper substrate to define a blue transmission opening, a green transmission opening, and a red transmission opening, which overlap the blue transmission region, the green transmission region, and the red transmission region, respectively; a color conversion layer including red color conversion particles and third scattering particles, and accommodated in the red transmission opening; a light emitting element layer on a lower substrate facing the upper substrate; and a filling material between the upper substrate and the lower substrate.

According to some embodiments, an average diameter of the second scattering particles may be greater than or equal to an average diameter of the first scattering particles.

According to some embodiments, the average diameter of the first scattering particles may be about 480 nm or less, and the average diameter of the second scattering particles may be about 550 nm or less.

According to some embodiments, each of the blue transmission opening and the green transmission opening defined by the partition wall may be filled with the filling material.

According to some embodiments, the color conversion layer may be spaced apart from each of the blue transmission region and the green transmission region in a plan view.

According to some embodiments, the light emitting element layer may include: a blue light emitting element layer configured to emit a blue light having a peak wavelength in a range of about 440 nm to about 480 nm; and a green light emitting element layer overlapping the blue light emitting element layer, and configured to emit a green light having a peak wavelength in a range of about 510 nm to about 550 nm.

According to some embodiments of the present disclosure, a display device includes: a blue color filter layer in a blue transmission region of an upper substrate, and including first scattering particles; a green color filter layer in a green transmission region of the upper substrate, and including second scattering particles; a red color filter layer in a red transmission region of the upper substrate; a light emitting element layer on a lower substrate facing the upper substrate; a partition wall on the light emitting element layer on the lower substrate to define a blue transmission opening, a green transmission opening, and a red transmission opening, which overlap the blue transmission region, the green transmission region, and the red transmission region, respectively; a color conversion layer including red color conversion particles and third scattering particles, and accommodated in the red transmission opening; and a filling material between the upper substrate and the lower substrate.

According to some embodiments, an average diameter of the second scattering particles may be greater than or equal to an average diameter of the first scattering particles.

According to some embodiments, the average diameter of the first scattering particles may be about 480 nm or less, and the average diameter of the second scattering particles may be about 550 nm or less.

According to some embodiments, each of the blue transmission opening and the green transmission opening defined by the partition wall may be filled with the filling material.

According to some embodiments, the color conversion layer may be spaced apart from each of the blue transmission region and the green transmission region in a plan view.

According to some embodiments, the light emitting element layer may include: a blue light emitting element layer configured to emit a blue light having a peak wavelength in a range of about 440 nm to about 480 nm; and a green light emitting element layer overlapping the blue light emitting element layer, and configured to emit a green light having a peak wavelength in a range of about 510 nm to about 550 nm.

According to some embodiments of the present disclosure, a display device includes: a light emitting element layer on a lower substrate; a partition wall on the light emitting element layer on the lower substrate to define a blue transmission opening, a green transmission opening, and a red transmission opening; a color conversion layer including red color conversion particles and third scattering particles, and accommodated in the red transmission opening; a blue color filter layer on the partition wall on the lower substrate, overlapping the blue transmission opening, and including first scattering particles; a green color filter layer on the partition wall on the lower substrate, overlapping the green transmission opening, and including second scattering particles; and a red color filter layer on the partition wall on the lower substrate, and overlapping the red transmission opening.

According to some embodiments, an average diameter of the second scattering particles may be greater than or equal to an average diameter of the first scattering particles.

According to some embodiments, the average diameter of the first scattering particles may be about 480 nm or less, and the average diameter of the second scattering particles may be about 550 nm or less.

According to some embodiments, the color conversion layer may be spaced apart from each of the blue transmission opening and the green transmission opening in a plan view.

According to some embodiments, the light emitting element layer may include: a blue light emitting element layer configured to emit a blue light having a peak wavelength in a range of about 440 nm to about 480 nm; and a green light emitting element layer overlapping the blue light emitting element layer, and configured to emit a green light having a peak wavelength in a range of about 510 nm to about 550 nm.

According to some embodiments, the display device may further include a planarization layer between the partition wall and the blue color filter layer, the green color filter layer, and the red color filter layer to fill the blue transmission opening and the green transmission opening.

According to some embodiments, the display device may further include an organic layer on the lower substrate to cover the blue color filter layer, the green color filter layer, and the red color filter layer.

According to some embodiments, the display device may further include an upper substrate on the organic layer.

According to some embodiments of the present disclosure, the display device may include the blue color filter layer including the first scattering particles. Accordingly, a blue light emitted from a light emitting element and passing through the blue color filter layer may be scattered by the first scattering particles, so that display quality of the display device can be relatively improved.

According to some embodiments of the present disclosure, the display device may include the green color filter layer including the second scattering particles. Accordingly, a green light emitted from the light emitting element and passing through the green color filter layer may be scattered by the second scattering particles, so that the display quality of the display device can be relatively improved.

However, the characteristics of embodiments according to the present disclosure are not limited to the above-described characteristics, and may be variously expanded without departing from the idea and scope of the present disclosure.

### BRIEF DESCRIPTION OF THE DRAWINGS

FIG. 1 is a perspective view for describing a display device according to some embodiments of the present disclosure.

FIG. 2 is a plan view illustrating further details of a lower structure included in the display device of FIG. 1 according to some embodiments of the present disclosure.

FIG. 3 is a sectional view illustrating further details of the lower structure of FIG. 2.

FIG. 4 is a plan view illustrating further details of an upper structure included in the display device of FIG. 1 according to some embodiments of the present disclosure.

FIG. 5 is a sectional view illustrating further details of the upper structure of FIG. 4 according to some embodiments.

FIG. 6 is a sectional view illustrating further details of the display device of FIG. 1 according to some embodiments of the present disclosure.

FIG. 7 is a perspective view illustrating further details of a display according to some embodiments of the present disclosure.

FIG. 8 is a sectional view illustrating further details of a lower structure included in the display device of FIG. 7 according to some embodiments of the present disclosure.

FIG. 9 is a sectional view illustrating further details of an upper structure included in the display device of FIG. 7 according to some embodiments of the present disclosure.

FIG. 10 is a sectional view illustrating further details of the display device of FIG. 7 according to some embodiments of the present disclosure.

FIG. 11 is a perspective view illustrating further details of a display device according to some embodiments of the present disclosure.

FIG. 12 is a sectional view illustrating further details of a lower structure included in the display device of FIG. 11 according to some embodiments of the present disclosure.

FIG. 13 is a sectional view illustrating further details of the display device of FIG. 11 according to some embodiments of the present disclosure.

### DETAILED DESCRIPTION

Hereinafter, a display device according to some embodiments of the present disclosure will be described in more detail with reference to the accompanying drawings. The same or similar reference numerals will be used for the same elements in the accompanying drawings.

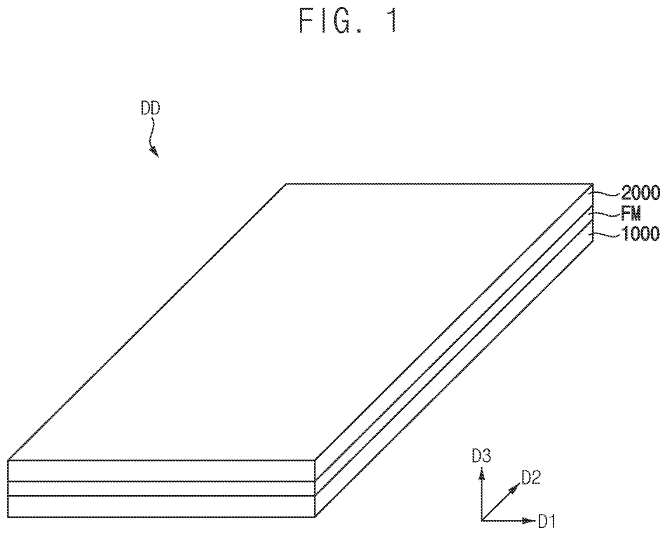

FIG. 1 is a perspective view for describing a display device according to some embodiments of the present disclosure.

Referring to FIG. 1, a display device DD may include a lower structure 1000, a filling material FM, and an upper structure 2000.

The lower structure 1000 may include a plurality of pixels. Each of the pixels may emit light, so that the display device DD may display images by combining light emitted from the pixels.

The upper structure 2000 may be located on the lower structure 1000. The upper structure 2000 may scatter the light emitted from the pixels, or convert wavelengths of the lights emitted from the pixels. In addition, the upper structure 2000 may selectively transmit a light having a specific color (or a light having a specific wavelength) among the light emitted from the lower structure 1000.

The filling material FM may be located between the upper structure 2000 and the lower structure 1000. The filling material FM may serve to couple the upper structure 2000 to the lower structure 1000 by filling an empty space between the upper structure 2000 and the lower structure 1000.

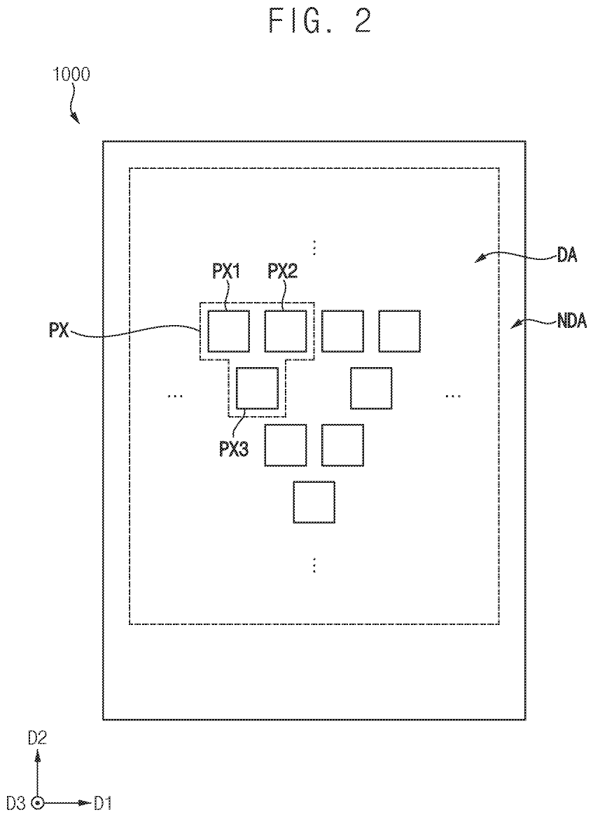

FIG. 2 is a plan view for describing a lower structure included in the display device of FIG. 1.

Referring to FIG. 2, the lower structure 1000 may be partitioned into a display area DA and a peripheral area NDA.

A pixel unit PX may be located in the display area DA. Pixel units PX may be repeatedly arranged over the entire display area DA. In addition, the pixel unit PX may include at least one sub-pixel. For example, the pixel unit PX may include a first sub-pixel PX1, a second sub-pixel PX2, and a third sub-pixel PX3. In this case, each of the first sub-pixel PX1, the second sub-pixel PX2, and the third sub-pixel PX3 may emit a light.

The peripheral area NDA may be located on at least one side of the display area DA. For example, as shown in FIG. 2, the peripheral area NDA may surround the display area DA (e.g., in a periphery or outside a footprint of the display area DA). A driving circuit (e.g., a scan driving circuit, a data driving circuit, etc.) configured to drive the pixel unit PX may be located in the peripheral area NDA. According to some embodiments, the peripheral area NDA may be omitted. In this case, the driving circuit may be located in the display area DA.

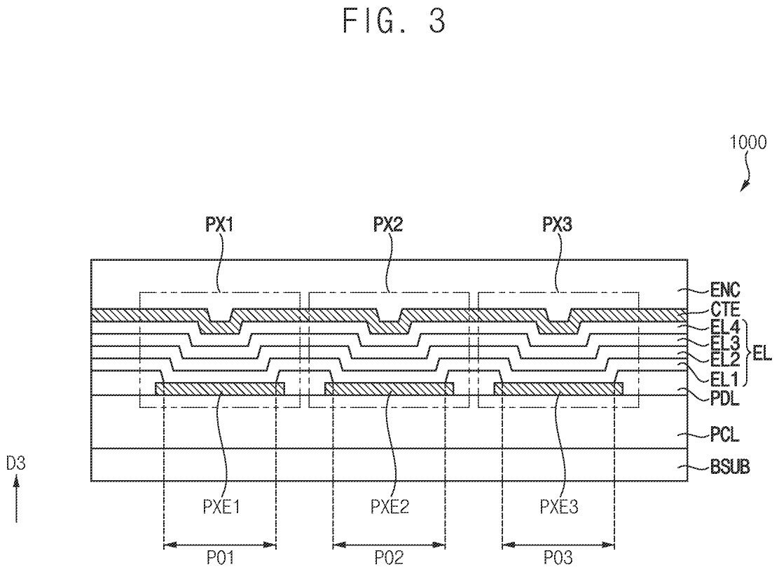

FIG. 3 is a sectional view for describing the lower structure of FIG. 2.

Referring to FIG. 3, the lower structure 1000 may include a lower substrate BSUB, a circuit layer PCL, a pixel defining layer PDL, a first pixel electrode PXE1, a second pixel electrode PXE2, a third pixel electrode PXE3, a light emitting element layer EL, a common electrode layer CTE, and an encapsulation layer ENC.

The lower substrate BSUB may include glass, plastic, and the like. According to some embodiments, at least a portion of the lower substrate BSUB may have flexibility, so that the lower substrate BSUB may have a flexible property.

The circuit layer PCL may be located on the lower substrate BSUB. The circuit layer PCL may include at least one transistor. For example, the circuit layer PCL may include: a first driving transistor electrically connected to the first pixel electrode PXE1; a second driving transistor electrically connected to the second pixel electrode PXE2; and a third driving transistor electrically connected to the third pixel electrode PXE3. According to some embodiments, the circuit layer PCL may further include at least one capacitor.

The first pixel electrode PXE1, the second pixel electrode PXE2, and the third pixel electrode PXE3 may be located on the circuit layer PCL. According to some embodiments, each of the first pixel electrode PXE1, the second pixel electrode PXE2, and the third pixel electrode PXE3 may be referred to as an anode electrode.

The pixel defining layer PDL may be located on the circuit layer PCL. The pixel defining layer PDL may define a first pixel opening PO1 opening the first pixel electrode PXE1, a second pixel opening PO2 opening the second pixel electrode PXE2, and a third pixel opening PO3 opening the third pixel electrode PXE3. According to some embodiments, the pixel defining layer PDL may include an organic insulating material.

The light emitting element layer EL may cover the pixel defining layer PDL, the first pixel electrode PXE1, the second pixel electrode PXE2, and the third pixel electrode PXE3. In this case, at least a portion of the light emitting element layer EL may be located inside each of the first pixel opening PO1, the second pixel opening PO2, and the third pixel opening PO3.

According to some embodiments, the light emitting element layer EL may include a plurality of light emitting element layers. For example, as shown in FIG. 3, the light emitting element layer EL may include a first light emitting element layer EL1, a second light emitting element layer EL2, a third light emitting element layer EL3, and a fourth light emitting element layer EL4, which are stacked to overlap each other. However, because the above configuration has been provided for illustrative purposes, the light emitting element layer EL may include two or three light emitting element layers, or at least five light emitting element layers. That is, in various embodiments, the light emitting layer EL may include any suitable number of layers according to the design of the display device.

According to some embodiments, some of the light emitting element layers may be blue light emitting element layers configured to emit blue lights, and some of the remaining light emitting element layers may be green light emitting element layers configured to emit green lights. For example, each of the first light emitting element layer EL1, the second light emitting element layer EL2, and the third light emitting element layer EL3 may be the blue light emitting element layer, and the fourth light emitting element layer EL4 may be the green light emitting element layer. In this case, the blue light may be defined as a light having a peak wavelength in a range of about 440 nm to about 480 nm, and the green light may be defined as a light having a peak wavelength in a range of about 510 nm to about 550 nm.

The common electrode layer CTE may be located on the light emitting element layer EL. According to some embodiments, the common electrode layer CTE may be referred to as a cathode electrode.

The first pixel electrode PXE1, the second pixel electrode PXE2, the third pixel electrode PXE3, the light emitting element layer EL, and the common electrode layer CTE described above may define the first sub-pixel PX1, the second sub-pixel PX2, and the third sub-pixel PX3. According to some embodiments, a portion of the first pixel electrode PXE1 exposed by the first pixel opening PO1, the light emitting element layer EL located on the portion of the first pixel electrode PXE1, and the common electrode layer CTE located on the portion of the first pixel electrode PXE1 may define the first sub-pixel PX1. In this case, the first pixel opening PO1 defined by the pixel defining layer PDL may serve to define a first sub-light emitting region, which is a region in which a light is substantially emitted from the first sub-pixel PX1.

Similarly, the second pixel electrode PXE2, the light emitting element layer EL, and the common electrode layer CTE may define the second sub-pixel PX2, and the third pixel electrode PXE3, the light emitting element layer EL, and the common electrode layer CTE may define the third sub-pixel PX3.

The encapsulation layer ENC may be located on the common electrode layer CTE. The encapsulation layer ENC may include at least one inorganic encapsulation layer and at least one organic encapsulation layer. For example, the encapsulation layer ENC may include: a first inorganic encapsulation layer located on the common electrode layer CTE; an organic encapsulation layer located on the first inorganic encapsulation layer; and a second inorganic encapsulation layer located on the organic encapsulation layer.

According to some embodiments, a light emission efficiency enhancement layer may be located between the encapsulation layer ENC and the common electrode layer CTE. The light emission efficiency enhancement layer may serve to enhance extraction efficiency of a light emitted from the light emitting element layer EL. For example, the light emission efficiency enhancement layer may have a top surface having a concavo-convex structure.

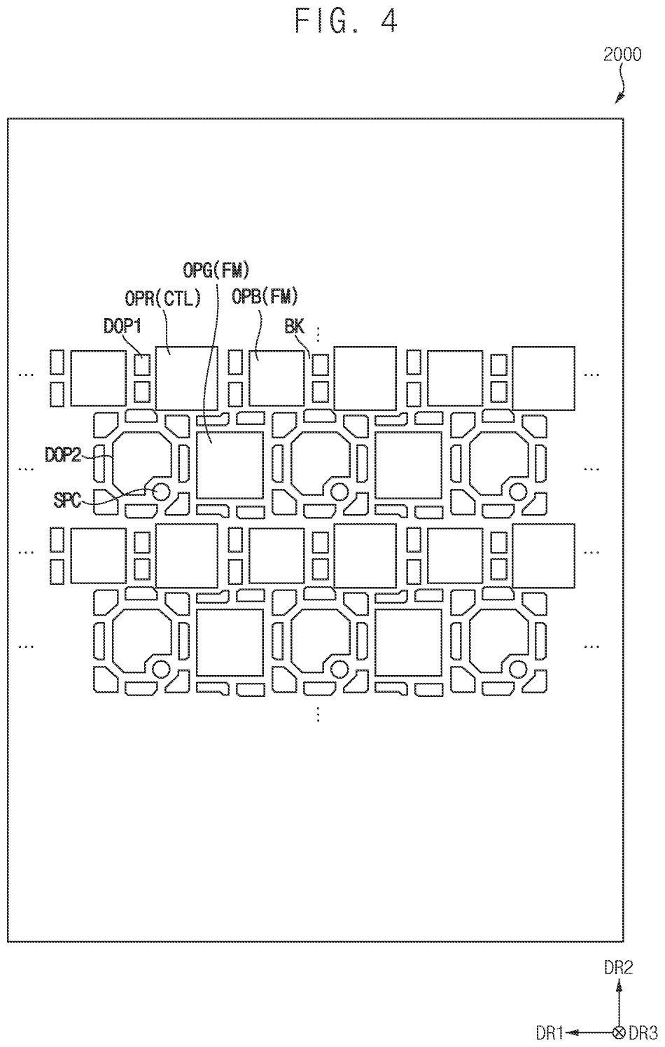

FIG. 4 is a plan view for describing an upper structure included in the display device of FIG. 1.

Referring to FIG. 4, the upper structure 2000 may be partitioned into a plurality of regions by a partition wall BK.

The partition wall BK may define a blue transmission opening OPB, a green transmission opening OPG, and a red transmission opening OPR. In this case, the blue transmission opening OPB may overlap the blue transmission region, the red transmission opening OPR may overlap the red transmission region, and the green transmission opening OPG may overlap the green transmission region.

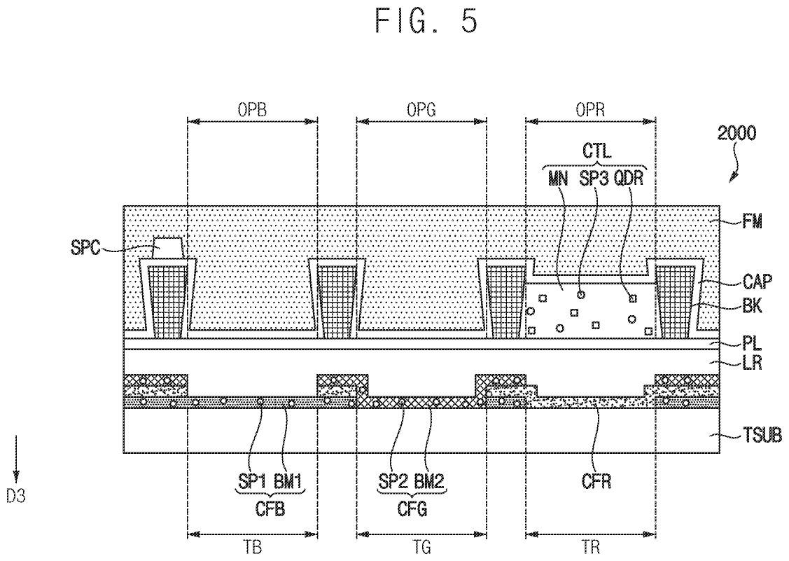

The blue transmission region may be a region that selectively transmits a blue light, the green transmission region may be a region that selectively transmits a green light, and the red transmission region may be a region that selectively transmits a red light. The blue transmission region, the green transmission region, and the red transmission region will be described below with reference to FIG. 5.

The blue transmission opening OPB and the red transmission opening OPR may be filled with the filling material FM. In addition, the red transmission opening OPR may be filled with a color conversion layer CTL.

According to some embodiments, the partition wall BK may further define a first dummy opening DOP1 and a second dummy opening DOP2. The first dummy opening DOP1 may be located between the blue transmission opening OPB and the green transmission opening OPG, which are adjacent to each other, between the green transmission opening OPG and the red transmission opening OPR, which are adjacent to each other, and between the red transmission opening OPR and the blue transmission opening OPB, which are adjacent to each other. In addition, the second dummy opening DOP2 may be surrounded by the first dummy opening DOP1. Each of the first dummy opening DOP1 and the second dummy opening DOP2 may serve to accommodate an erroneously jetted ink in an inkjet process of forming the color conversion layer CTL and the filling material FM.

FIG. 5 is a sectional view for describing the upper structure of FIG. 4.

Referring to FIG. 5, the upper structure 2000 may include an upper substrate TSUB, a blue color filter layer CFB, a green color filter layer CFG, a red color filter layer CFR, a refraction layer LR, a protective layer PL, a partition wall BK, a color conversion layer CTL, a capping layer CAP, and a spacer SPC.

The upper substrate TSUB may include glass, plastic, and the like. According to some embodiments, at least a portion of the upper substrate TSUB may have flexibility, so that the upper substrate TSUB may have a flexible property.

Each of the blue color filter layer CFB, the green color filter layer CFG, and the red color filter layer CFR may be located on the upper substrate TSUB.

The blue color filter layer CFB may selectively transmit a blue light. For example, the blue color filter layer CFB may selectively transmit a light having a peak wavelength in a range of about 440 nm to about 480 nm.

The green color filter layer CFG may selectively transmit a green light. For example, the green color filter layer CFG may selectively transmit a light having a peak wavelength in a range of about 510 nm to about 550 nm.

The red color filter layer CFR may selectively transmit a red light. For example, the red color filter layer CFR may selectively transmit a light having a peak wavelength in a range of about 640 nm to about 700 nm.

The blue color filter layer CFB, the green color filter layer CFG, and the red color filter layer CFR may overlap each other in a partial region on the upper substrate TSUB. The partial region may be referred to as a light blocking region, and the blue color filter layer CFB, the green color filter layer CFG, and the red color filter layer CFR overlapping each other in the light blocking region may block a light.

Meanwhile, a region in which the blue color filter layer CFB is located alone on the upper substrate TSUB may be defined as a blue transmission region TB. The blue transmission region TB may be a region that selectively transmits a blue light.

Similarly, a region in which the green color filter layer CFG is located alone on the upper substrate TSUB may be defined as a green transmission region TG, and a region in which the red color filter layer CFR is located alone on the upper substrate TSUB may be defined as a red transmission region TR. In this case, the green transmission region TG may be a region that selectively transmits a green light, and the red transmission region TR may be a region that selectively transmits a red light.

According to some embodiments, the blue color filter layer CFB may include a first base member BM1 and first scattering particles SP1.

The first base member BM1 may serve to selectively transmit a blue light. The first base member BM1 may include an organic material in which a blue pigment (or a blue dye) is dispersed. For example, the first base member BM1 may include an acryl resin, an epoxy resin, a polyimide resin, or the like in which the blue pigment (or the blue dye) is dispersed.

The first scattering particles SP1 may be dispersed and located within the first base member BM1. The first scattering particles SP1 may serve to scatter a light passing through the blue color filter layer CFB.

According to some embodiments, the first scattering particles SP1 may include titanium dioxide particles, zinc oxide particles, aluminum oxide particles, silicon oxide particles, hollow silica particles, and the like.

According to some embodiments, the green color filter layer CFG may include a second base member BM2 and second scattering particles SP2.

The second base member BM2 may serve to selectively transmit a green light. The second base member BM2 may include an organic material in which a green pigment (or a green dye) is dispersed. For example, the second base member BM2 may include an acryl resin, an epoxy resin, a polyimide resin, or the like in which the green pigment (or the green dye) is dispersed.

The second scattering particles SP2 may be dispersed and located within the second base member BM2. The second scattering particles SP2 may serve to scatter a light passing through the green color filter layer CFG.

According to some embodiments, the second scattering particles SP2 may include titanium dioxide particles, zinc oxide particles, aluminum oxide particles, silicon oxide particles, hollow silica particles, and the like.

The refraction layer LR may be located on the upper substrate TSUB, and may cover the blue color filter layer CFB, the green color filter layer CFG, and the red color filter layer CFR. The refraction layer LR may include a material having a relatively low refractive index (or a material having a relatively high refractive index).

The protective layer PL may be located on the refraction layer LR. According to some embodiments, the protective layer PL may include an inorganic insulating material, and may serve to protect the refraction layer LR.

The partition wall BK may be located on the protective layer PL. As described above with reference to FIG. 4, the partition wall BK may define the blue transmission opening OPB, the green transmission opening OPG, and the red transmission opening OPR. In this case, as shown in FIG. 5, the blue transmission opening OPB may overlap the blue transmission region TB, the green transmission opening OPG may overlap the green transmission region TG, and the red transmission opening OPR may overlap the red transmission region TR.

The color conversion layer CTL may be accommodated in the red transmission opening OPR defined by the partition wall BK. Accordingly, the color conversion layer CTL may overlap the red color filter layer CFR located in the red transmission region TR, and may not overlap each of the green color filter layer CFG located in the green transmission region TG and the blue color filter layer CFB located in the blue transmission region TB. The color conversion layer CTL may include a monomer MN, red color conversion particles QDR, and third scattering particles SP3.

The red color conversion particles QDR and the third scattering particles SP3 may be dispersed and located within the monomer MN. According to some embodiments, the monomer MN may include an epoxy-based monomer, an ester-based monomer, and the like.

The red color conversion particles QDR may convert a color of an incident light into a red color. For example, the red color conversion particles QDR may be quantum dots. In this case, the red color conversion particles QDR may be selected from the group consisting of a group II-VI compound, a group IV-VI compound, a group IV element, a group IV compound, and a combination thereof. The third scattering particles SP3 may serve to scatter a light passing through the color conversion layer CTL.

The capping layer CAP may cover the partition wall BK and the color conversion layer CTL. According to some embodiments, the capping layer CAP may include an inorganic insulating material.

The spacer SPC may be located on the capping layer CAP. In this case, the spacer SPC may overlap the partition wall BK. According to some embodiments, the spacer SPC may be formed only on the partition wall BK, and may not overlap the blue transmission opening OPB, the green transmission opening OPG, and the red transmission opening OPR.

The filling material FM may be located on the upper structure 2000. For example, the filling material FM may be located on the capping layer CAP. In this case, according to some embodiments, the blue transmission opening OPB and the green transmission opening OPG may be filled with the filling material FM. For example, unlike the red transmission opening OPR, the color conversion layer may not be located within the blue transmission opening OPB and the green transmission opening OPG, so that the blue transmission opening OPB and the green transmission opening OPG may be filled with the filling material FM located on the upper structure 2000.

According to some embodiments, the filling material FM may include an organic material having a relatively high refractive index. For example, the refractive index of the filling material FM may be about 1.6 to about 1.8. For example, the filling material FM may include a urethane-based resin, an epoxy-based resin, an acryl-based resin, and the like.

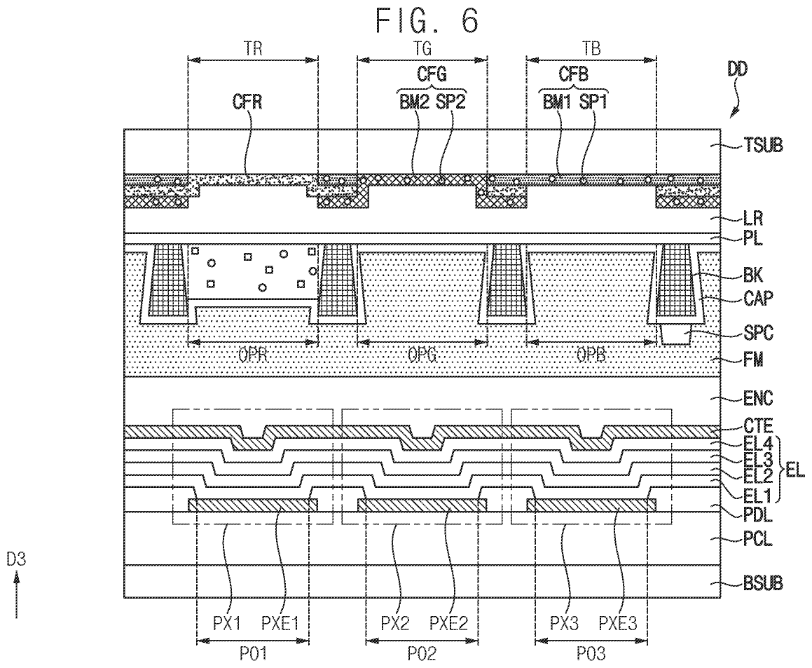

FIG. 6 is a sectional view for describing the display device of FIG. 1.

Referring to FIG. 6, the upper structure 2000 may face the lower structure 1000. In this case, the filling material FM may be located between the upper structure 2000 and the lower structure 1000 so as to couple the upper structure 2000 and the lower structure 1000 to each other.

In this case, the first pixel opening PO1, the red transmission opening OPR, and the red transmission region TR may overlap each other, the second pixel opening PO2, the green transmission opening OPG, and the green transmission region TG may overlap each other, and the third pixel opening PO3, the blue transmission opening OPB, and the blue transmission region TB may overlap each other.

Accordingly, a light emitted from the light emitting element layer EL of the first sub-pixel PX1 may sequentially pass through the color conversion layer CTL accommodated in the red transmission opening OPR and the red color filter layer CFR located in the red transmission region TR so as to be visually recognized or perceived as a red light by a user of the display device DD.

According to some embodiments, as described above with reference to FIG. 3, the light emitting element layer EL may include a blue light emitting element layer (e.g., EL1, EL2, EL3) and a green light emitting element layer (e.g., EL4), which overlap each other, the blue light emitting element layer may emit a blue light, and the green light emitting element layer may emit a green light.

In this case, the blue light emitted from the blue light emitting element layer and the green light emitted from the green light emitting element layer may pass through the color conversion layer CTL so as to be converted into a red light by the red color conversion particles QDR while being scattered by the third scattering particles SP3. Thereafter, the red light may pass through the red color filter layer CFR so as to be visually recognized or perceived by the user of the display device DD.

In addition, a light emitted from the second sub-pixel PX2 may sequentially pass through the filling material FM accommodated in the green transmission opening OPG and the green color filter layer CFG located in the green transmission region TG so as to be visually recognized or perceived as a green light by the user of the display device DD.

According to some embodiments, each of the blue light emitted from the blue light emitting element layer and the green light emitted from the green light emitting element layer may pass through the filling material FM in the green transmission opening OPG, and may be incident on the green color filter layer CFG located in the green transmission region TG. Thereafter, the green color filter layer CFG may block the blue light emitted from the blue light emitting element layer, and selectively transmit only the green light emitted from the green light emitting element layer. In this case, the green light emitted from the green light emitting element layer may be scattered by the second scattering particles SP2, and may be visually recognized or perceived by the user of the display device DD.

Similarly, a light emitted from the third sub-pixel PX3 may sequentially pass through the filling material FM accommodated in the blue transmission opening OPB and the blue color filter layer CFB located in the blue transmission region TB so as to be visually recognized or perceived as a blue light by the user of the display device DD.

According to some embodiments, each of the blue light emitted from the blue light emitting element layer and the green light emitted from the green light emitting element layer may pass through the filling material FM in the blue transmission opening OPB, and may be incident on the blue color filter layer CFB located in the blue transmission region TB. Thereafter, the blue color filter layer CFB may block the green light emitted from the green light emitting element layer, and selectively transmit only the blue light emitted from the blue light emitting element layer. In this case, the blue light emitted from the blue light emitting element layer may be scattered by the first scattering particles SP1, and may be visually recognized or perceived by the user of the display device DD.

According to some embodiments, an average diameter of the second scattering particles SP2 included in the green color filter layer CFG may be greater than or equal to an average diameter of the first scattering particles SP1 included in the blue color filter layer CFB.

The green color filter layer CFG may selectively transmit a green light, and the blue color filter layer CFB may selectively transmit a blue light. In this case, the green light may have any wavelength within a first wavelength range, the blue light may have any wavelength within a second wavelength range, and the wavelength of the green light may be larger or smaller than the wavelength of the blue light.

Because the second scattering particles SP2 have to effectively scatter the green light, the average diameter of the second scattering particles SP2 has to be smaller than the wavelength of the green light. Similarly, because the first scattering particles SP1 have to effectively scatter the blue light, the average diameter of the first scattering particles SP1 has to be smaller than the wavelength of the blue light.

Therefore, in order to effectively scatter each of the green light passing through the green color filter layer CFG and the blue light passing through the blue color filter layer CFB, the average diameter of the second scattering particles SP2 included in the green color filter layer CFG may be greater than or equal to the average diameter of the first scattering particles SP1 included in the blue color filter layer CFB.

In this case, the average diameter of the first scattering particles SP1 may be about 480 nm or less, and the average diameter of the second scattering particles SP2 may be about 550 nm or less. As described above, because the blue light may have a peak wavelength in a range of about 440 nm to about 480 nm, the average diameter of the first scattering particles SP1 to effectively scatter the blue light may be about 480 nm or less. Similarly, because the green light may have a peak wavelength in a range of about 510 nm to about 550 nm, the average diameter of the second scattering particles SP2 to effectively scatter the green light may be about 550 nm or less.

For example, the average diameter of the first scattering particles SP1 may be 240 nm, which is half of 480 nm, and the average diameter of the second scattering particles SP2 may be 275 nm, which is half of 550 nm. As another example, each of the average diameter of the first scattering particles SP1 and the average diameter of the second scattering particles SP2 may be 200 nm.

In order to improve light output efficiency of the display device DD, each of a content of the first scattering particles SP1 included in the blue color filter layer CFB and a content of the second scattering particles SP2 included in the green color filter layer CFG may have various values.

According to some embodiments, the first scattering particles SP1 may serve to improve side light output efficiency of the display device DD by randomly scattering a blue light, which travels in a third direction DR3, in a direction intersecting the third direction DR3. Similarly, the second scattering particles SP2 may serve to improve the side light output efficiency of the display device DD by randomly scattering a green light, which travels in the third direction DR3, in the direction intersecting the third direction DR3.

Accordingly, when the image displayed on the display device DD has to be displayed at a relatively wide viewing angle, the blue color filter layer CFB may include a relatively large amount of first scattering particles SP1, and the green color filter layer CFG may also include a relatively large amount of second scattering particles SP2.

On the contrary, when the image displayed on the display device DD has to be displayed at a relatively narrow viewing angle, the blue color filter layer CFB may include a relatively small amount of first scattering particles SP1, and the green color filter layer CFG may also include a relatively small amount of second scattering particles SP2.

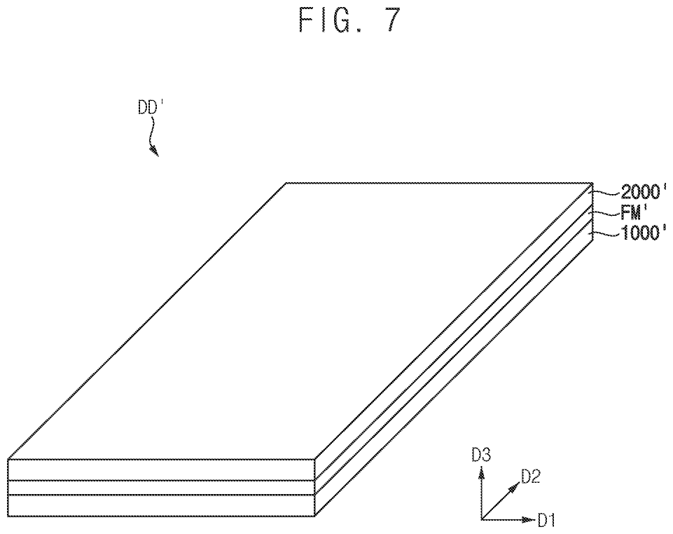

FIG. 7 is a perspective view for describing a display device according to some embodiments of the present disclosure.

Referring to FIG. 7, a display device DD′ may include a lower structure 1000, a filling material FM′, and an upper structure 2000.

The lower structure 1000′ may include a plurality of pixels. Each of the pixels may emit a light, so that the display device DD′ may display an image by combining the lights emitted from the pixels. In addition, the lower structure 1000′ may convert wavelengths of lights emitted from some of the pixels.

The upper structure 2000′ may be located on the lower structure 1000. The upper structure 2000′ may selectively transmit a light having a specific color (or a light having a specific wavelength) among the light emitted from the pixels.

The filling material FM′ may be located between the upper structure 2000′ and the lower structure 1000. The filling material FM′ may serve to couple the upper structure 2000′ to the lower structure 1000′ by filling an empty space between the upper structure 2000′ and the lower structure 1000.

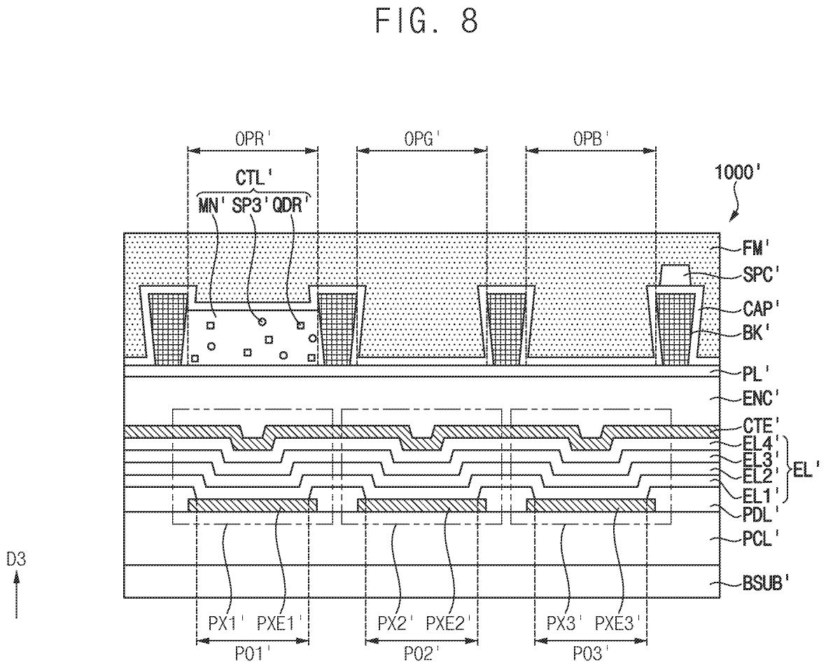

FIG. 8 is a sectional view for describing a lower structure included in the display device of FIG. 7.

Referring to FIG. 8, the lower structure 1000′ may include a lower substrate BSUB′, a circuit layer PCL′, a pixel defining layer PDL′, a first pixel electrode PXE1′, a second pixel electrode PXE2′, a third pixel electrode PXE3′, a light emitting element layer EL′, a common electrode layer CTE′, an encapsulation layer ENC′, a protective layer PL′, a partition wall BK′, a color conversion layer CTL′, a capping layer CAP′, and a spacer SPC′.

The lower substrate BSUB′, the circuit layer PCL′, the pixel defining layer PDL′, the first pixel electrode PXE1′, the second pixel electrode PXE2′, the third pixel electrode PXE3′, the light emitting element layer EL′, the common electrode layer CTE′, and the encapsulation layer ENC′ may be substantially identical to the lower substrate BSUB, the circuit layer PCL, the pixel defining layer PDL, the first pixel electrode PXE1, the second pixel electrode PXE2, the third pixel electrode PXE3, the light emitting element layer EL, the common electrode layer CTE, and the encapsulation layer ENC described with reference to FIGS. 2, 3, and 6. Therefore, redundant descriptions of components will be partially omitted below.

The pixel defining layer PDL′ may define a first pixel opening PO1′ opening the first pixel electrode PXE1′, a second pixel opening PO2′ opening the second pixel electrode PXE2′, and a third pixel opening PO3′ opening the third pixel electrode PXE3′, and at least a portion of the light emitting element layer EL′ may be located inside each of the first pixel opening PO1′, the second pixel opening PO2′, and the third pixel opening PO3′.

The first pixel electrode PXE1′, the second pixel electrode PXE2′, the third pixel electrode PXE3′, the light emitting element layer EL′, and the common electrode layer CTE′ described above may define a first sub-pixel PX1′, a second sub-pixel PX2′, and a third sub-pixel PX3′. According to some embodiments, a portion of the first pixel electrode PXE1′ exposed by the first pixel opening PO1′, the light emitting element layer EL′ located on the portion of the first pixel electrode PXE1′, and the common electrode layer CTE′ located on the portion of the first pixel electrode PXE1′ may define the first sub-pixel PX1′. In this case, the first pixel opening PO1′ defined by the pixel defining layer PDL′ may serve to define a first sub-light emitting region, which is a region in which a light is substantially emitted from the first sub-pixel PX1′.

Similarly, the second pixel electrode PXE2′, the light emitting element layer EL′, and the common electrode layer CTE′ may define the second sub-pixel PX2′, and the third pixel electrode PXE3′, the light emitting element layer EL′, and the common electrode layer CTE′ may define the third sub-pixel PX3′.

According to some embodiments, the light emitting element layer EL′ may include a plurality of light emitting element layers. For example, as shown in FIG. 8, the light emitting element layer EL′ may include a first light emitting element layer EL1′, a second light emitting element layer EL2′, a third light emitting element layer EL3′, and a fourth light emitting element layer EL4′, which are stacked to overlap each other. However, because the above configuration has been provided for illustrative purposes, the light emitting element layer EL′ may include two to three light emitting element layers, or at least five light emitting element layers.

According to some embodiments, some of the light emitting element layers may be blue light emitting element layers configured to emit blue lights, and some of the remaining light emitting element layers may be green light emitting element layers configured to emit green lights. For example, each of the first light emitting element layer EL1′, the second light emitting element layer EL2′, and the third light emitting element layer EL3′ may be the blue light emitting element layer, and the fourth light emitting element layer EL4′ may be the green light emitting element layer. In this case, the blue light may be defined as a light having a peak wavelength in a range of about 440 nm to about 480 nm, and the green light may be defined as a light having a peak wavelength in a range of about 510 nm to about 550 nm.

The protective layer PL′ may be located on the encapsulation layer ENC′. According to some embodiments, the protective layer PL′ may include an inorganic insulating material.

The partition wall BK′ may be located on the protective layer PL. The partition wall BK′ may define a blue transmission opening OPB′, a green transmission opening OPG′, and a red transmission opening OPR′. In this case, as shown in FIG. 8, the blue transmission opening OPB′ may overlap the third pixel opening PO3′, the green transmission opening OPG′ may overlap the second pixel opening PO2′, and the red transmission opening OPR′ may overlap the first pixel opening PO1′.

The color conversion layer CTL′ may be accommodated in the red transmission opening OPR′ defined by the partition wall BK′. Accordingly, the color conversion layer CTL′ may overlap the first pixel opening PO1′, and may not overlap each of the second pixel opening PO2′ and the third pixel opening PO3′. The color conversion layer CTL′ may include a monomer MN′, red color conversion particles QDR′, and third scattering particles SP3′.

The red color conversion particles QDR′ and the third scattering particles SP3′ may be dispersed and located within the monomer MN′. According to some embodiments, the monomer MN′ may include an epoxy-based monomer, an ester-based monomer, and the like.

The red color conversion particles QDR′ may convert a color of an incident light into a red color. For example, the red color conversion particles QDR′ may be quantum dots. In this case, the red color conversion particles QDR′ may be selected from the group consisting of a group II-VI compound, a group IV-VI compound, a group IV element, a group IV compound, and a combination thereof. The third scattering particles SP3′ may serve to scatter a light passing through the color conversion layer CTL′.

The capping layer CAP′ may cover the partition wall BK′ and the color conversion layer CTL′. According to some embodiments, the capping layer CAP′ may include an inorganic insulating material.

The spacer SPC′ may be located on the capping layer CAP′. In this case, the spacer SPC′ may overlap the partition wall BK′. According to some embodiments, the spacer SPC′ may be formed only on the partition wall BK′, and may not overlap the blue transmission opening OPB′, the green transmission opening OPG′ and the red transmission opening OPR′.

The filling material FM′ may be located on the lower structure 1000′. For example, the filling material FM′ may be located on the capping layer CAP′. According to some embodiments, the blue transmission opening OPB′ and the green transmission opening OPG′ may be filled with the filling material FM′. According to some embodiments, unlike the red transmission opening OPR′, the color conversion layer may not be located within the blue transmission opening OPB′ and the green transmission opening OPG′, so that the blue transmission opening OPB′ and the green transmission opening OPG′ may be filled with the filling material FM′ located on the lower structure 1000′.

According to some embodiments, the filling material FM′ may include an organic material having a relatively high refractive index. For example, the refractive index of the filling material FM′ may be about 1.6 to about 1.8. For example, the filling material FM′ may include a urethane-based resin, an epoxy-based resin, an acryl-based resin, and the like.

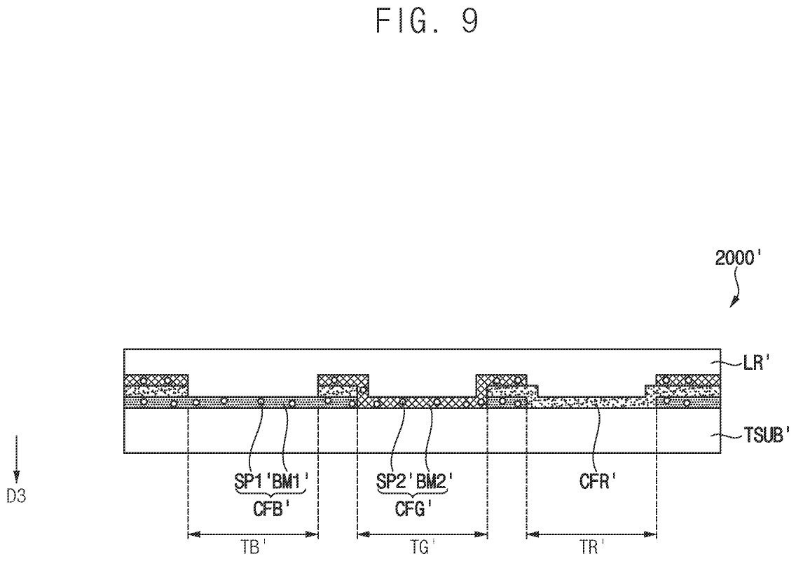

FIG. 9 is a sectional view for describing an upper structure included in the display device of FIG. 7.

Referring to FIG. 9, the upper structure 2000′ may include an upper substrate TSUB′, a blue color filter layer CFB′, a green color filter layer CFG′, a red color filter layer CFR′, and a refraction layer LR′.

The upper substrate TSUB′, the blue color filter layer CFB′, the green color filter layer CFG′, the red color filter layer CFR′, and the refraction layer LR′ may be substantially identical to the upper substrate TSUB, the blue color filter layer CFB, the green color filter layer CFG, the red color filter layer CFR, and the refraction layer LR described with reference to FIGS. 4, 5, and 6. Therefore, redundant descriptions of components will be partially omitted below.

The blue color filter layer CFB′ may selectively transmit a blue light. For example, the blue color filter layer CFB′ may selectively transmit a light having a peak wavelength in a range of about 440 nm to about 480 nm.

The green color filter layer CFG′ may selectively transmit a green light. For example, the green color filter layer CFG′ may selectively transmit a light having a peak wavelength in a range of about 510 nm to about 550 nm.

The red color filter layer CFR′ may selectively transmit a red light. For example, the red color filter layer CFR′ may selectively transmit a light having a peak wavelength in a range of about 640 nm to about 700 nm.

The blue color filter layer CFB′, the green color filter layer CFG′, and the red color filter layer CFR′ may overlap each other in a partial region on the upper substrate TSUB′. The partial region may be referred to as a light blocking region, and the blue color filter layer CFB′, the green color filter layer CFG′, and the red color filter layer CFR′ overlapping each other in the light blocking region may block a light.

Meanwhile, a region in which the blue color filter layer CFB′ is located alone on the upper substrate TSUB′ may be defined as a blue transmission region TB′. The blue transmission region TB′ may be a region that selectively transmits a blue light.

Similarly, a region in which the green color filter layer CFG′ is located alone on the upper substrate TSUB′ may be defined as a green transmission region TG′, and a region in which the red color filter layer CFR′ is located alone on the upper substrate TSUB′ may be defined as a red transmission region TR′. In this case, the green transmission region TG′ may be a region that selectively transmits a green light, and the red transmission region TR′ may be a region that selectively transmits a red light.

According to some embodiments, the blue color filter layer CFB′ may include a first base member BM1′ and first scattering particles SP1′.

The first base member BM1′ may serve to selectively transmit a blue light. The first base member BM1′ may include an organic material in which a blue pigment (or a blue dye) is dispersed. For example, the first base member BM1′ may include an acryl resin, an epoxy resin, a polyimide resin, or the like in which the blue pigment (or the blue dye) is dispersed.

The first scattering particles SP1′ may be dispersed and located within the first base member BM1′. The first scattering particles SP1′ may serve to scatter a light passing through the blue color filter layer CFB′.

According to some embodiments, the first scattering particles SP1′ may include titanium dioxide particles, zinc oxide particles, aluminum oxide particles, silicon oxide particles, hollow silica particles, and the like.

According to some embodiments, the green color filter layer CFG′ may include a second base member BM2′ and second scattering particles SP2′.

The second base member BM2′ may serve to selectively transmit a green light. The second base member BM2′ may include an organic material in which a green pigment (or a green dye) is dispersed. For example, the second base member BM2′ may include an acryl resin, an epoxy resin, a polyimide resin, or the like in which the green pigment (or the green dye) is dispersed.

The second scattering particles SP2′ may be dispersed and located within the second base member BM2′. The second scattering particles SP2′ may serve to scatter a light passing through the green color filter layer CFG′.

According to some embodiments, the second scattering particles SP2′ may include titanium dioxide particles, zinc oxide particles, aluminum oxide particles, silicon oxide particles, hollow silica particles, and the like.

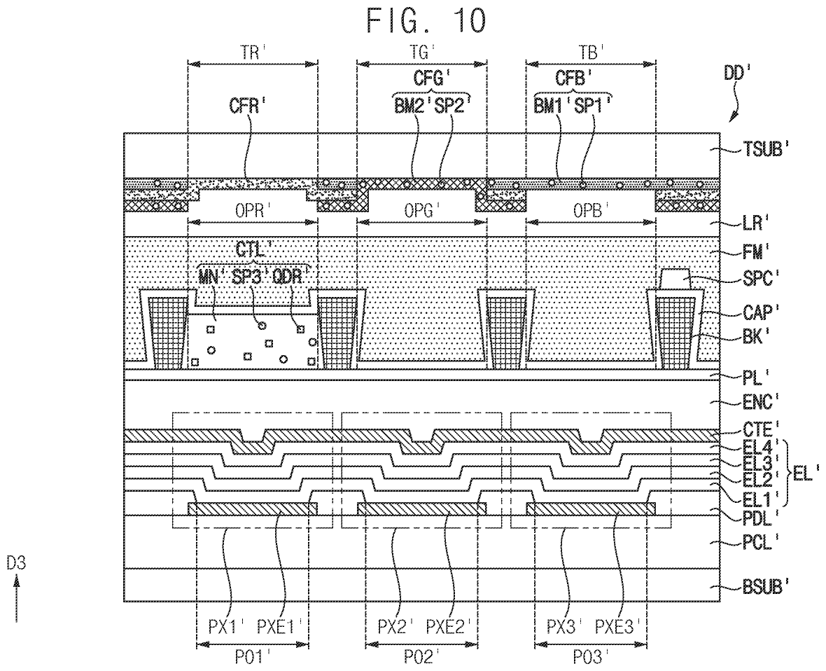

FIG. 10 is a sectional view for describing the display device of FIG. 7.

Referring to FIG. 10, the upper structure 2000′ may face the lower structure 1000. In this case, the filling material FM′ may be located between the upper structure 2000′ and the lower structure 1000′ so as to couple the upper structure 2000′ and the lower structure 1000′ to each other.

The first pixel opening PO1′, the red transmission opening OPR′, and the red transmission region TR′ may overlap each other, the second pixel opening PO2′, the green transmission opening OPG′, and the green transmission region TG′ may overlap each other, and the third pixel opening PO3′, the blue transmission opening OPB′, and the blue transmission region TB′ may overlap each other.

Accordingly, a light emitted from the light emitting element layer EL′ of the first sub-pixel PX1′ may sequentially pass through the color conversion layer CTL′ accommodated in the red transmission opening OPR′ and the red color filter layer CFR′ located in the red transmission region TR′ so as to be visually recognized or perceived as a red light by a user of the display device DD′.

According to some embodiments, as described above with reference to FIG. 8, the light emitting element layer EL′ may include a blue light emitting element layer (e.g., EL1′, EL2′, EL3′) and a green light emitting element layer (e.g., EL4′), which overlap each other, the blue light emitting element layer may emit a blue light, and the green light emitting element layer may emit a green light.

In this case, the blue light emitted from the blue light emitting element layer and the green light emitted from the green light emitting element layer may pass through the color conversion layer CTL′ so as to be converted into a red light by the red color conversion particles QDR′ while being scattered by the third scattering particles SP3′. Thereafter, the red light may pass through the red color filter layer CFR′ so as to be visually recognized or perceived by the user of the display device DD′.

In addition, a light emitted from the second sub-pixel PX2′ may sequentially pass through the filling material FM′ accommodated in the green transmission opening OPG′ and the green color filter layer CFG′ located in the green transmission region TG′ so as to be visually recognized or perceived as a green light by the user of the display device DD′.

According to some embodiments, each of the blue light emitted from the blue light emitting element layer and the green light emitted from the green light emitting element layer may pass through the filling material FM′ in the green transmission opening OPG′, and may be incident on the green color filter layer CFG′ located in the green transmission region TG′. Thereafter, the green color filter layer CFG′ may block the blue light emitted from the blue light emitting element layer, and selectively transmit only the green light emitted from the green light emitting element layer. In this case, the green light emitted from the green light emitting element layer may be scattered by the second scattering particles SP2′, and may be visually recognized or perceived by the user of the display device DD′.

Similarly, a light emitted from the third sub-pixel PX3′ may sequentially pass through the filling material FM′ accommodated in the blue transmission opening OPB′ and the blue color filter layer CFB′ located in the blue transmission region TB′ so as to be visually recognized or perceived as a blue light by the user of the display device DD′.

According to some embodiments, each of the blue light emitted from the blue light emitting element layer and the green light emitted from the green light emitting element layer may pass through the filling material FM′ in the blue transmission opening OPB′, and may be incident on the blue color filter layer CFB′ located in the blue transmission region TB′. Thereafter, the blue color filter layer CFB′ may block the green light emitted from the green light emitting element layer, and selectively transmit only the blue light emitted from the blue light emitting element layer. In this case, the blue light emitted from the blue light emitting element layer may be scattered by the first scattering particles SP1′, and may be visually recognized or perceived by the user of the display device DD′.

According to some embodiments, an average diameter of the second scattering particles SP2′ included in the green color filter layer CFG′ may be greater than or equal to an average diameter of the first scattering particles SP1′ included in the blue color filter layer CFB′.

The green color filter layer CFG′ may selectively transmit a green light, and the blue color filter layer CFB′ may selectively transmit a blue light. In this case, the green light may have any wavelength within a first wavelength range, the blue light may have any wavelength within a second wavelength range, and the wavelength of the green light may be larger or smaller than the wavelength of the blue light.

Because the second scattering particles SP2′ have to effectively scatter the green light, the average diameter of the second scattering particles SP2′ has to be smaller than the wavelength of the green light. Similarly, because the first scattering particles SP1′ have to effectively scatter the blue light, the average diameter of the first scattering particles SP1′ has to be smaller than the wavelength of the blue light.

Therefore, in order to effectively scatter each of the green light passing through the green color filter layer CFG′ and the blue light passing through the blue color filter layer CFB′, the average diameter of the second scattering particles SP2′ included in the green color filter layer CFG′ may be greater than or equal to the average diameter of the first scattering particles SP1′ included in the blue color filter layer CFB′.

In this case, the average diameter of the first scattering particles SP1′ may be about 480 nm or less, and the average diameter of the second scattering particles SP2′ may be about 550 nm or less. As described above, because the blue light may have a peak wavelength in a range of about 440 nm to about 480 nm, the average diameter of the first scattering particles SP1′ to effectively scatter the blue light may be about 480 nm or less. Similarly, because the green light may have a peak wavelength in a range of about 510 nm to about 550 nm, the average diameter of the second scattering particles SP2′ to effectively scatter the green light may be about 550 nm or less.

For example, the average diameter of the first scattering particles SP1′ may be 240 nm, which is half of 480 nm, and the average diameter of the second scattering particles SP2′ may be 275 nm, which is half of 550 nm. As another example, each of the average diameter of the first scattering particles SP1′ and the average diameter of the second scattering particles SP2′ may be 200 nm.

In order to improve light output efficiency of the display device DD′, each of a content of the first scattering particles SP1′ included in the blue color filter layer CFB′ and a content of the second scattering particles SP2′ included in the green color filter layer CFG′ may have various values.

According to some embodiments, the first scattering particles SP1′ may serve to improve side light output efficiency of the display device DD′ by randomly scattering a blue light, which travels in the third direction DR3, in the direction intersecting the third direction DR3. Similarly, the second scattering particles SP2′ may serve to improve the side light output efficiency of the display device DD′ by randomly scattering a green light, which travels in the third direction DR3, in the direction intersecting the third direction DR3.

Accordingly, when the image displayed on the display device DD′ has to be displayed at a relatively wide viewing angle, the blue color filter layer CFB′ may include a relatively large amount of first scattering particles SP1′, and the green color filter layer CFG′ may also include a relatively large amount of second scattering particles SP2′.

On the contrary, when the image displayed on the display device DD′ has to be displayed at a relatively narrow viewing angle, the blue color filter layer CFB′ may include a relatively small amount of first scattering particles SP1′, and the green color filter layer CFG′ may also include a relatively small amount of second scattering particles SP2′.

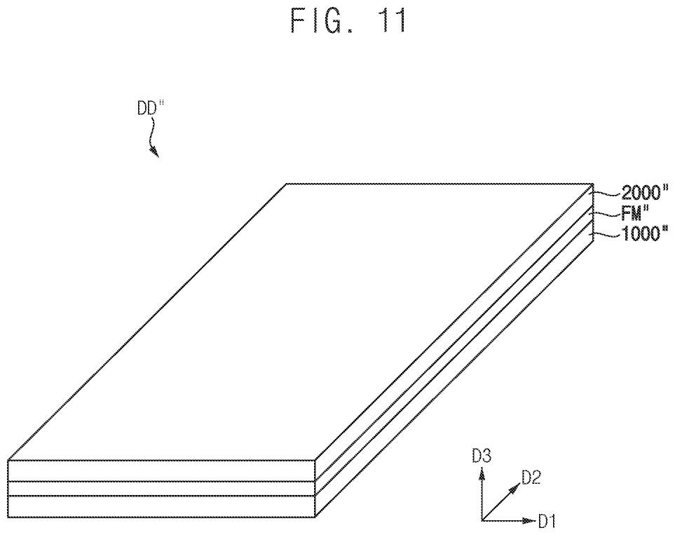

FIG. 11 is a perspective view for describing a display device according to some embodiments of the present disclosure.

Referring to FIG. 11, a display device DD″ may include a lower structure 1000″, an organic layer FM″, and an upper structure 2000″.

The lower structure 1000″ may include a plurality of pixels. Each of the pixels may emit a light, so that the display device DD″ may display an image by combining the lights emitted from the pixels.

In addition, the lower structure 1000″ may convert lights emitted from some of the pixels, and may selectively transmit a light having a specific color (or a light having a specific wavelength) among the lights emitted from the pixels.

The upper structure 2000″ may be located on the lower structure 1000″. The upper structure 2000″ may include a material having relatively high rigidity, so that the upper structure 2000″ may serve to protect the lower structure 1000″ from an external impact. According to some embodiments, the upper structure 2000″ may be omitted.

The organic layer FM″ may be located between the upper structure 2000″ and the lower structure 1000″. The organic layer FM″ may serve to couple the upper structure 2000″ to the lower structure 1000″ by filling an empty space between the upper structure 2000″ and the lower structure 1000″.

According to some embodiments, when the upper structure 2000″ is omitted, the organic layer FM″ may also serve protect the lower structure 1000″ from an external impact. In this case, the organic layer FM″ may include an organic material having relatively high rigidity.

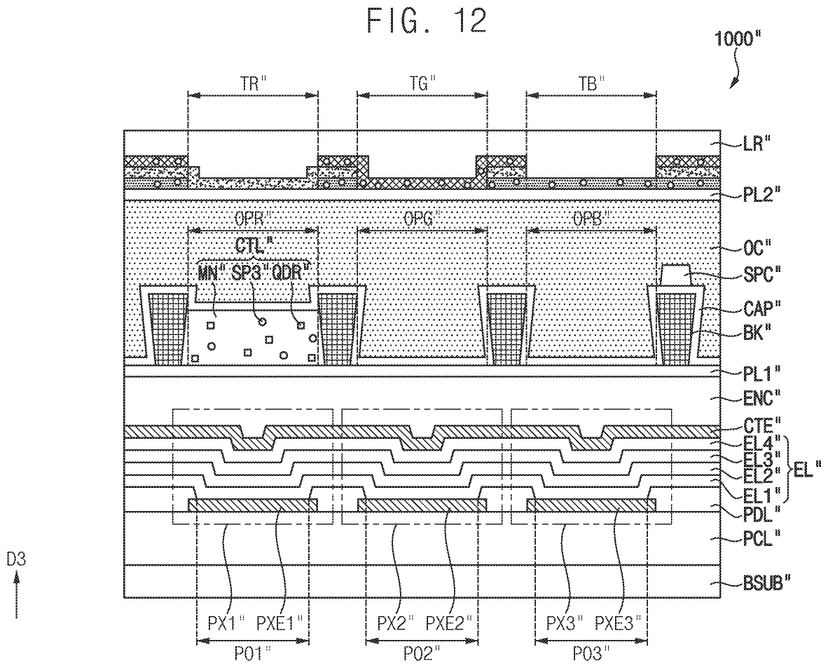

FIG. 12 is a sectional view for describing a lower structure included in the display device of FIG. 11.

Referring to FIG. 12, the lower structure 1000″ may include a lower substrate BSUB″, a circuit layer PCL″, a pixel defining layer PDL″, a first pixel electrode PXE1″, a second pixel electrode PXE2″, a third pixel electrode PXE3″, a light emitting element layer EL″, a common electrode layer CTE″, an encapsulation layer ENC″, a first protective layer PL1″, a partition wall BK″, a color conversion layer CTL″, a capping layer CAP″, a spacer SPC″, a planarization layer OC″, a second protective layer PL2″, a blue color filter layer CFB″, a green color filter layer CFG″, and a red color filter layer CFR″.

The lower substrate BSUB″, the circuit layer PCL″, the pixel defining layer PDL″, the first pixel electrode PXE1″, the second pixel electrode PXE2″, the third pixel electrode PXE3″, the light emitting element layer EL″, the common electrode layer CTE″, the encapsulation layer ENC″, the first protective layer PL1″, the partition wall BK″, the color conversion layer CTL″, the capping layer CAP″, and the spacer SPC″ may be substantially identical to the lower substrate BSUB′, the circuit layer PCL′, the pixel defining layer PDL′, the first pixel electrode PXE1′, the second pixel electrode PXE2′, the third pixel electrode PXE3′, the light emitting element layer EL′, the common electrode layer CTE′, the encapsulation layer ENC′, the protective layer PL′, the partition wall BK′, the color conversion layer CTL′, the capping layer CAP′, and the spacer SPC′ described with reference to FIG. 8. Therefore, redundant descriptions of components will be partially omitted below.

The pixel defining layer PDL″ may define a first pixel opening PO1″ opening the first pixel electrode PXE1″, a second pixel opening PO2″ opening the second pixel electrode PXE2″, and a third pixel opening PO3″ opening the third pixel electrode PXE3″, and at least a portion of the light emitting element layer EL″ may be located inside each of the first pixel opening PO1″, the second pixel opening PO2″, and the third pixel opening PO3″.

The first pixel electrode PXE1″, the second pixel electrode PXE2″, the third pixel electrode PXE3″, the light emitting element layer EL″, and the common electrode layer CTE″ described above may define a first sub-pixel PX1″, a second sub-pixel PX2″, and a third sub-pixel PX3″. According to some embodiments, a portion of the first pixel electrode PXE1″ exposed by the first pixel opening PO1″, the light emitting element layer EL″ located on the portion of the first pixel electrode PXE1″, and the common electrode layer CTE″ located on the portion of the first pixel electrode PXE1″ may define the first sub-pixel PX1″. In this case, the first pixel opening PO1″ defined in the pixel defining layer PDL″ may serve to define a first sub-light emitting region, which is a region in which a light is substantially emitted from the first sub-pixel PX1″.

Similarly, the second pixel electrode PXE2″, the light emitting element layer EL″, and the common electrode layer CTE″ may define the second sub-pixel PX2″, and the third pixel electrode PXE3″, the light emitting element layer EL″, and the common electrode layer CTE″ may define the third sub-pixel PX3″.

According to some embodiments, the light emitting element layer EL″ may include a plurality of light emitting element layers. For example, as shown in FIG. 12, the light emitting element layer EL″ may include a first light emitting element layer EL1″, a second light emitting element layer EL2″, a third light emitting element layer EL3″, and a fourth light emitting element layer EL4″, which are stacked to overlap each other. However, because the above configuration has been provided for illustrative purposes, the light emitting element layer EL″ may include two to three light emitting element layers, or at least five light emitting element layers.

According to some embodiments, some of the light emitting element layers may be blue light emitting element layers configured to emit blue lights, and some of the remaining light emitting element layers may be green light emitting element layers configured to emit green lights. For example, each of the first light emitting element layer EL1″, the second light emitting element layer EL2″, and the third light emitting element layer EL3″ may be the blue light emitting element layer, and the fourth light emitting element layer EL4″ may be the green light emitting element layer. In this case, the blue light may be defined as a light having a peak wavelength in a range of about 440 nm to about 480 nm, and the green light may be defined as a light having a peak wavelength in a range of about 510 nm to about 550 nm.

In addition, the partition wall BK″ may define a blue transmission opening OPB″, a green transmission opening OPG″, and a red transmission opening OPR″. In this case, as shown in FIG. 12, the blue transmission opening OPB″ may overlap the third pixel opening PO3″, the green transmission opening OPG″ may overlap the second pixel opening PO2″, and the red transmission opening OPR″ may overlap the first pixel opening PO1″.

The color conversion layer CTL″ may be accommodated in the red transmission opening OPR″ defined by the partition wall BK″. Accordingly, the color conversion layer CTL″ may overlap the first pixel opening PO1″, and may not overlap each of the second pixel opening PO2″ and the third pixel opening PO3″. The color conversion layer CTL″ may include a monomer MN″, red color conversion particles QDR″, and third scattering particles SP3″.

The red color conversion particles QDR″ and the third scattering particles SP3″ may be dispersed and located within the monomer MN″. According to some embodiments, the monomer MN″ may include an epoxy-based monomer, an ester-based monomer, and the like.

The red color conversion particles QDR″ may convert a color of an incident light into a red color. For example, the red color conversion particles QDR″ may be quantum dots. In this case, the red color conversion particles QDR″ may be selected from the group consisting of a group II-VI compound, a group IV-VI compound, a group IV element, a group IV compound, and a combination thereof. The third scattering particles SP3″ may serve to scatter a light passing through the color conversion layer CTL″.

The planarization layer OC″ may be located on the capping layer CAP″. According to some embodiments, the blue transmission opening OPB″ and the green transmission opening OPG″ may be filled with the planarization layer OC″. According to some embodiments, unlike the red transmission opening OPR″, the color conversion layer may not be located within the blue transmission opening OPB″ and the green transmission opening OPG″, so that the blue transmission opening OPB″ and the green transmission opening OPG″ may be filled with the planarization layer OC″ located on the capping layer CAP″.

According to some embodiments, the planarization layer OC″ may include an organic material having a relatively high refractive index. For example, the refractive index of the planarization layer OC″ may be about 1.6 to about 1.8. For example, the planarization layer OC″ may include a urethane-based resin, an epoxy-based resin, an acryl-based resin, and the like.

The second protective layer PL2″ may be located on the planarization layer OC″. According to some embodiments, the second protective layer PL2″ may include an inorganic insulating material.

The blue color filter layer CFB″, the green color filter layer CFG″, and the red color filter layer CFR″ may be located on the second protective layer PL2″.

The blue color filter layer CFB″ may selectively transmit a blue light. For example, the blue color filter layer CFB″ may selectively transmit a light having a peak wavelength in a range of about 440 nm to about 480 nm.

The green color filter layer CFG″ may selectively transmit a green light. For example, the green color filter layer CFG″ may selectively transmit a light having a peak wavelength in a range of about 510 nm to about 550 nm.

The red color filter layer CFR″ may selectively transmit a red light. For example, the red color filter layer CFR″ may selectively transmit a light having a peak wavelength in a range of about 640 nm to about 700 nm.

The blue color filter layer CFB″, the green color filter layer CFG″, and the red color filter layer CFR″ may overlap each other in a partial region. The partial region may be referred to as a light blocking region, and the blue color filter layer CFB″, the green color filter layer CFG″, and the red color filter layer CFR″ overlapping each other in the light blocking region may block a light.

Meanwhile, a region in which the blue color filter layer CFB″ is located alone may be defined as a blue transmission region TB″. The blue transmission region TB″ may be a region that selectively transmits a blue light.

Similarly, a region in which the green color filter layer CFG″ is located alone may be defined as a green transmission region TG″, and a region in which the red color filter layer CFR″ is located alone may be defined as a red transmission region TR″. In this case, the green transmission region TG″ may be a region that selectively transmits a green light, and the red transmission region TR″ may be a region that selectively transmits a red light.

According to some embodiments, the blue color filter layer CFB″ may include a first base member BM1″ and first scattering particles SP1″.

The first base member BM1″ may serve to selectively transmit a blue light. The first base member BM1″ may include an organic material in which a blue pigment (or a blue dye) is dispersed. For example, the first base member BM1″ may include an acryl resin, an epoxy resin, a polyimide resin, or the like in which the blue pigment (or the blue dye) is dispersed.

The first scattering particles SP1″ may be dispersed and located within the first base member BM1″. The first scattering particles SP1″ may serve to scatter a light passing through the blue color filter layer CFB″.

According to some embodiments, the first scattering particles SP1″ may include titanium dioxide particles, zinc oxide particles, aluminum oxide particles, silicon oxide particles, hollow silica particles, and the like.

According to some embodiments, the green color filter layer CFG″ may include a second base member BM2″ and second scattering particles SP2″.

The second base member BM2″ may serve to selectively transmit a green light. The second base member BM2″ may include an organic material in which a green pigment (or a green dye) is dispersed. For example, the second base member BM2″ may include an acryl resin, an epoxy resin, a polyimide resin, or the like in which the green pigment (or the green dye) is dispersed.

The second scattering particles SP2″ may be dispersed and located within the second base member BM2″. The second scattering particles SP2″ may serve to scatter a light passing through the green color filter layer CFG″.

According to some embodiments, the second scattering particles SP2″ may include titanium dioxide particles, zinc oxide particles, aluminum oxide particles, silicon oxide particles, hollow silica particles, and the like.

The organic layer FM″ may be located on the lower structure 1000″. For example, the organic layer FM″ may cover the blue color filter layer CFB″, the green color filter layer CFG″, and the red color filter layer CFR″.

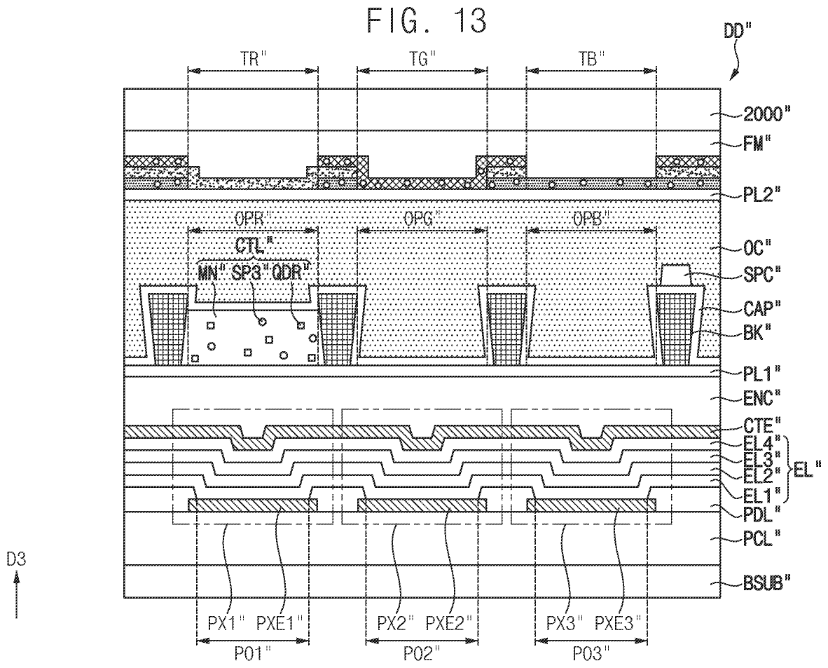

FIG. 13 is a sectional view for describing the display device of FIG. 11.

Referring to FIG. 13, the upper structure 2000″ may face the lower structure 1000″. In this case, the organic layer FM″ may be located between the upper structure 2000″ and the lower structure 1000″ so as to couple the upper structure 2000″ and the lower structure 1000″ to each other.

According to some embodiments, the upper structure 2000″ may be omitted. In this case, the organic layer FM″ may include an organic material having relatively high rigidity.

The first pixel opening PO1″, the red transmission opening OPR″, and the red transmission region TR″ may overlap each other, the second pixel opening PO2″, the green transmission opening OPG″, and the green transmission region TG″ may overlap each other, and the third pixel opening PO3″, the blue transmission opening OPB″, and the blue transmission region TB″ may overlap each other.

Accordingly, a light emitted from the light emitting element layer EL″ of the first sub-pixel PX1″ may sequentially pass through the color conversion layer CTL″ accommodated in the red transmission opening OPR″ and the red color filter layer CFR″ located in the red transmission region TR″ so as to be visually recognized or perceived as a red light by a user of the display device DD″.

According to some embodiments, as described above with reference to FIG. 12, the light emitting element layer EL″ may include a blue light emitting element layer (e.g., EL1″, EL2″, EL3″) and a green light emitting element layer (e.g., EL4″), which overlap each other, the blue light emitting element layer may emit a blue light, and the green light emitting element layer may emit a green light.

In this case, the blue light emitted from the blue light emitting element layer and the green light emitted from the green light emitting element layer may pass through the color conversion layer CTL″ so as to be converted into a red light by the red color conversion particles QDR″ while being scattered by the third scattering particles SP3″. Thereafter, the red light may pass through the red color filter layer CFR″ so as to be visually recognized or perceived by the user of the display device DD″.

In addition, a light emitted from the second sub-pixel PX2″ may sequentially pass through the planarization layer OC″ accommodated in the green transmission opening OPG″ and the green color filter layer CFG″ located in the green transmission region TG″ so as to be visually recognized or perceived as a green light by the user of the display device DD″.

According to some embodiments, each of the blue light emitted from the blue light emitting element layer and the green light emitted from the green light emitting element layer may pass through the planarization layer OC″ in the green transmission opening OPG″, and may be incident on the green color filter layer CFG″ located in the green transmission region TG″. Thereafter, the green color filter layer CFG″ may block the blue light emitted from the blue light emitting element layer, and selectively transmit only the green light emitted from the green light emitting element layer. In this case, the green light emitted from the green light emitting element layer may be scattered by the second scattering particles SP2″, and may be visually recognized or perceived by the user of the display device DD″.

Similarly, a light emitted from the third sub-pixel PX3″ may sequentially pass through the planarization layer OC″ accommodated in the blue transmission opening OPB″ and the blue color filter layer CFB″ located in the blue transmission region TB″ so as to be visually recognized or perceived as a blue light by the user of the display device DD″.

According to some embodiments, each of the blue light emitted from the blue light emitting element layer and the green light emitted from the green light emitting element layer may pass through the planarization layer OC″ in the blue transmission opening OPB″, and may be incident on the blue color filter layer CFB″ located in the blue transmission region TB″. Thereafter, the blue color filter layer CFB″ may block the green light emitted from the green light emitting element layer, and selectively transmit only the blue light emitted from the blue light emitting element layer. In this case, the blue light emitted from the blue light emitting element layer may be scattered by the first scattering particles SP1″, and may be visually recognized or perceived by the user of the display device DD″.

According to some embodiments, an average diameter of the second scattering particles SP2″ included in the green color filter layer CFG″ may be greater than or equal to an average diameter of the first scattering particles SP1″ included in the blue color filter layer CFB″.

The green color filter layer CFG″ may selectively transmit a green light, and the blue color filter layer CFB″ may selectively transmit a blue light. In this case, the green light may have any wavelength within a first wavelength range, the blue light may have any wavelength within a second wavelength range, and the wavelength of the green light may be larger or smaller than the wavelength of the blue light.

Because the second scattering particles SP2″ have to effectively scatter the green light, the average diameter of the second scattering particles SP2″ has to be smaller than the wavelength of the green light. Similarly, because the first scattering particles SP1″ have to effectively scatter the blue light, the average diameter of the first scattering particles SP1″ has to be smaller than the wavelength of the blue light.

Therefore, in order to effectively scatter each of the green light passing through the green color filter layer CFG″ and the blue light passing through the blue color filter layer CFB″, the average diameter of the second scattering particles SP2″ included in the green color filter layer CFG″ may be greater than or equal to the average diameter of the first scattering particles SP1″ included in the blue color filter layer CFB″.

In this case, the average diameter of the first scattering particles SP1″ may be about 480 nm or less, and the average diameter of the second scattering particles SP2″ may be about 550 nm or less. As described above, because the blue light may have a peak wavelength in a range of about 440 nm to about 480 nm, the average diameter of the first scattering particles SP1″ to effectively scatter the blue light may be about 480 nm or less. Similarly, because the green light may have a peak wavelength in a range of about 510 nm to about 550 nm, the average diameter of the second scattering particles SP2″ to effectively scatter the green light may be about 550 nm or less.

For example, the average diameter of the first scattering particles SP1″ may be 240 nm, which is half of 480 nm, and the average diameter of the second scattering particles SP2″ may be 275 nm, which is half of 550 nm. As another example, each of the average diameter of the first scattering particles SP1″ and the average diameter of the second scattering particles SP2″ may be 200 nm.

In order to improve light output efficiency of the display device DD″, each of a content of the first scattering particles SP1″ included in the blue color filter layer CFB″ and a content of the second scattering particles SP2″ included in the green color filter layer CFG″ may have various values.

According to some embodiments, the first scattering particles SP1″ may serve to improve side light output efficiency of the display device DD″ by randomly scattering a blue light, which travels in the third direction DR3, in the direction intersecting the third direction DR3. Similarly, the second scattering particles SP2″ may serve to improve the side light output efficiency of the display device DD″ by randomly scattering a green light, which travels in the third direction DR3, in the direction intersecting the third direction DR3.

Accordingly, when the image displayed on the display device DD″ has to be displayed at a relatively wide viewing angle, the blue color filter layer CFB″ may include a relatively large amount of first scattering particles SP1″, and the green color filter layer CFG″ may also include a relatively large amount of second scattering particles SP2″.

On the contrary, when the image displayed on the display device DD″ has to be displayed at a relatively narrow viewing angle, the blue color filter layer CFB″ may include a relatively small amount of first scattering particles SP1″, and the green color filter layer CFG″ may also include a relatively small amount of second scattering particles SP2″.

Aspects of some embodiments of the present disclosure may be applied to a display device and various electronic devices including the display device. For example, aspects of some embodiments of the present disclosure may be applied to a smart phone, a smart pad, a smart watch, a tablet PC, a vehicle navigation system, a television, a computer monitor, a head-mounted display, and the like.

Although aspects of some embodiments of the present disclosure have been described above, it will be understood by those of ordinary skill in the art that various changes and modifications can be made to the present disclosure without departing from the idea and scope of the present disclosure as set forth in the appended claims, and their equivalents.

What is claimed is:

1. A display device comprising:
a blue color filter layer in a blue transmission region of an upper substrate, and including first scattering particles;
a green color filter layer in a green transmission region of the upper substrate, and including second scattering particles;
a red color filter layer in a red transmission region of the upper substrate;
a partition wall on the upper substrate and defining a blue transmission opening, a green transmission opening, and a red transmission opening, which overlap the blue transmission region, the green transmission region, and the red transmission region, respectively;
a color conversion layer including red color conversion particles and third scattering particles, and accommodated in the red transmission opening;
a light emitting element layer on a lower substrate facing the upper substrate; and
a filling material between the upper substrate and the lower substrate.

2. The display device of claim 1, wherein an average diameter of the second scattering particles is greater than or equal to an average diameter of the first scattering particles.

3. The display device of claim 2, wherein the average diameter of the first scattering particles is 480 nm or less, and
the average diameter of the second scattering particles is 550 nanometers (nm) or less.

4. The display device of claim 1, wherein each of the blue transmission opening and the green transmission opening defined by the partition wall is filled with the filling material.

5. The display device of claim 1, wherein the color conversion layer is spaced apart from each of the blue transmission region and the green transmission region in a plan view.

6. The display device of claim 1, wherein the light emitting element layer includes:
a blue light emitting element layer configured to emit a blue light having a peak wavelength in a range of 440 nanometers (nm) to 480 nm; and
a green light emitting element layer overlapping the blue light emitting element layer, and configured to emit a green light having a peak wavelength in a range of 510 nm to 550 nm.

7. A display device comprising:
a blue color filter layer in a blue transmission region of an upper substrate, and including first scattering particles;
a green color filter layer in a green transmission region of the upper substrate, and including second scattering particles;
a red color filter layer in a red transmission region of the upper substrate;
a light emitting element layer on a lower substrate facing the upper substrate;
a partition wall on the light emitting element layer on the lower substrate and defining a blue transmission opening, a green transmission opening, and a red transmission opening, which overlap the blue transmission region, the green transmission region, and the red transmission region, respectively;
a color conversion layer including red color conversion particles and third scattering particles, and accommodated in the red transmission opening; and
a filling material between the upper substrate and the lower substrate.

8. The display device of claim 7, wherein an average diameter of the second scattering particles is greater than or equal to an average diameter of the first scattering particles.

9. The display device of claim 8, wherein the average diameter of the first scattering particles is 480 nanometers (nm) or less, and
the average diameter of the second scattering particles is 550 nm or less.

10. The display device of claim 7, wherein each of the blue transmission opening and the green transmission opening defined by the partition wall is filled with the filling material.

11. The display device of claim 7, wherein the color conversion layer is spaced apart from each of the blue transmission region and the green transmission region in a plan view.

12. The display device of claim 7, wherein the light emitting element layer includes:
a blue light emitting element layer configured to emit a blue light having a peak wavelength in a range of 440 nanometers (nm) to 480 nm; and
a green light emitting element layer overlapping the blue light emitting element layer, and configured to emit a green light having a peak wavelength in a range of 510 nm to 550 nm.

13. A display device comprising:
a light emitting element layer on a lower substrate;
a partition wall on the light emitting element layer on the lower substrate to define a blue transmission opening, a green transmission opening, and a red transmission opening;
a color conversion layer including red color conversion particles and third scattering particles, and accommodated in the red transmission opening;
a blue color filter layer on the partition wall on the lower substrate, overlapping the blue transmission opening, and including first scattering particles;
a green color filter layer on the partition wall on the lower substrate, overlapping the green transmission opening, and including second scattering particles; and
a red color filter layer on the partition wall on the lower substrate, and overlapping the red transmission opening.

14. The display device of claim 13, wherein an average diameter of the second scattering particles is greater than or equal to an average diameter of the first scattering particles.

15. The display device of claim 14, wherein the average diameter of the first scattering particles is 480 nanometers (nm) or less, and
the average diameter of the second scattering particles is 550 nm or less.

16. The display device of claim 13, wherein the color conversion layer is spaced apart from each of the blue transmission opening and the green transmission opening in a plan view.

17. The display device of claim 13, wherein the light emitting element layer includes:
a blue light emitting element layer configured to emit a blue light having a peak wavelength in a range of 440 nanometers (nm) to 480 nm; and
a green light emitting element layer overlapping the blue light emitting element layer, and configured to emit a green light having a peak wavelength in a range of 510 nm to 550 nm.

18. The display device of claim 13, further comprising a planarization layer between the partition wall and the blue color filter layer, the green color filter layer, and the red color filter layer to fill the blue transmission opening and the green transmission opening.

19. The display device of claim 13, further comprising an organic layer on the lower substrate to cover the blue color filter layer, the green color filter layer, and the red color filter layer.

20. The display device of claim 19, further comprising an upper substrate on the organic layer.
